(19) United States
(12) Patent Application Publication
(10) Pub. No.: US 2008/0017908 A1
(43) Pub. Date: Jan. 24, 2008

(54) Semiconductor memory device and method of fabricating the same

(76) Inventors: Min-hee Cho, Suwon-si (KR); Sung-eui Kim, Suwon-si (KR); Won-tae Hwang, Yongin-si (KR); Jin-hye Bae, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/826,590

(22) Filed: Jul. 17, 2007

(30) Foreign Application Priority Data
Jul. 18, 2006 (KR) 10-2006-0066939

(51) Int. Cl. H01L 29/94; H01L 21/8242

(52) U.S. Cl. 257/311; 438/397; 257/E29.345; 257/E21.647

(57) ABSTRACT

Exemplary embodiments relate to a semiconductor memory device and method of fabricating the same. The semiconductor member device may include a semiconductor substrate, a plurality of storage node contact plugs formed above the semiconductor substrate, and a plurality of storage node electrodes, each of the plurality of storage node electrodes may be located respectively above each of the plurality of storage node contact plugs. Each of the storage node electrodes may include a cylindrical body and a generally Y-shaped connection portion extending from the cylindrical body and interfacing the storage node contact plugs.

### BACKGROUND OF THE INVENTION

1. Field of the Invention

Exemplary embodiments relate to a semiconductor memory device and a method of fabricating the same. More particularly, exemplary embodiments relate to a semiconductor memory device and a method of fabricating the same, in which a lower surface area of a capacitor may be increased.

2. Description of the Related Art

In the development of fabrication for semiconductor memory devices, decreases in the size of transistors and increase integration functions of the semiconductor memory have been achieved. In particular, in the area of memory cells, e.g., dynamic random access memories (DRAMs), the size of the memory cells have decreased while increasing the integration function.

A DRAM may typically include one transistor and one capacitor. The capacitor may be classified as a stack-type capacitor or a trench-type capacitor.

In designing DRAM for stack-type capacitors, the manufacturer should account for: increasing the height of storage electrodes, increasing effective surface area using, for example, hemi-spherical grains (HSGs), and/or using an area inside and outside of a cylinder using one cylinder storage (OCS) electrodes, so as to obtain capacitance required in a small area due to limited design rules.

In cylinder type storage electrodes, the size of an inner hole may be reduced due to the limited design rules, and the size of a lower hole may also decrease as the height of the storage electrode increases. The reduction in size of the lower hole may occur rapidly in an etch stopper layer. Accordingly, when a dielectric layer is deposited along the surface of the storage node electrodes, the dielectric layer may not be deposited on a lower portion of the storage electrodes.

Further, in order to increase the area of a lower electrode, wet etching on a mold for forming storage electrodes may be performed so as to increase the size of the side of the inner hole of the cylinder type storage electrode. In this case, however, the overall size of the inner hole may increase, and thus, possibly creating a short circuit between the adjacent storage electrodes. Further, when the overall size of the inner hole increases, buried contacts (BCs) located at the side as well as buried contacts located at the lower portion may be exposed. Therefore, a short circuit may also occur between the buried contacts.

### SUMMARY OF THE INVENTION

Exemplary embodiments are therefore directed to a semiconductor memory device and method of fabricating the same that substantially overcomes one or more of the problems of the related art.

It is therefore a feature of exemplary embodiments to provide a semiconductor memory device and a method of fabricating the same by forming storage node electrodes having lower portions that may have rounded (or curved) side walls and being generally Y-shaped.

It is therefore another feature of exemplary embodiments to provide a reduced width of a portion coming in contact with a storage node contact plug, so as to prevent and/or reduce separation of the storage node electrode from the storage node contact plug.

It is therefore yet another feature of exemplary embodiments to provide side walls of a storage node electrode that may be located in an etch stopper layer as being rounded (or curved), so as to increase a surface area of the storage node electrode. The increase surface area may result in an increase in capacitance.

It is therefore yet another feature of exemplary embodiments to prevent and/or reduce a dielectric layer from non-uniformly being deposited even on the lower portion of the storage node electrode due to the rapid step at the etch stopper layer.

At least one of the above and other features of exemplary embodiments related to a semiconductor memory device including a semiconductor substrate, a plurality of storage node contact plugs formed above the semiconductor substrate, and a plurality of storage node electrodes, each of the plurality of storage node electrodes may be located respectively above each of the plurality of storage node contact plugs. Each of the storage node electrodes may include a cylindrical body and a generally Y-shaped connection portion extending from the cylindrical body and interfacing the storage node contact plugs.

At least one of the above and other features of exemplary embodiments relate to a method of fabricating a semiconductor memory device. The method may include forming a semiconductor substrate, forming a plurality of storage node contact plugs above the semiconductor substrate, and forming a plurality of storage node electrodes, wherein each of the plurality of storage node electrodes may be located respectively above each of the plurality of storage node contact plugs. Each of the storage node electrodes may include a cylindrical body and a generally Y-shaped connection portion extending from the cylindrical body and interfacing the storage node contact plugs.

At least one of the above and other features of exemplary embodiments relate to a method of fabricating a semiconductor memory device. The method may include laminating a buffer insulating layer, an etch stopper layer, and a sacrificial insulating layer on storage node contact plugs that may be formed above a semiconductor substrate, selectively performing an anisotropic etching process on the sacrificial insulating layer until the etch stopper layer may be exposed so as to form cylindrical body forming-holes, performing an isotropic etching process on a portion of the stop etch layer that may be exposed through the cylindrical body forming-holes, such that a lower portion of each of the cylindrical body forming-holes is rounded, performing an anisotropic etching process on the remaining portion of the etch stopper layer and the buffer insulating layer so as to form storage node forming-holes that may be connected to the cylindrical body forming-holes and may have a generally Y-shaped lower portions that expose the surface of the storage node contact plugs, and conformally forming storage node electrodes along the storage node forming-holes.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIGS. 1A and 1B illustrate cross-sectional views of a semiconductor memory device according to exemplary embodiments; and

FIGS. 2 to 8 illustrate cross-sectional views of stages of a process of manufacturing the semiconductor memory device according to exemplary embodiments.

### DETAILED DESCRIPTION OF THE INVENTION

Korean Patent Application No. 10-2006-0066939 filed on Jul. 18, 2006 in the Korean Intellectual Property Office, and entitled: “Semiconductor Memory Device and Method of Fabricating the Same,” is incorporated by reference herein in its entirety.

Exemplary embodiments will now be described more fully hereinafter with reference to the accompanying drawings. The invention may, however, be embodied in many different forms and should not be construed as being limited to the exemplary embodiments set forth herein. Rather, these exemplary embodiments are provided so that this disclosure will be thorough and complete, and will fully convey the concept of the invention to those skilled in the art. Like reference numerals refer to like elements throughout the specification.

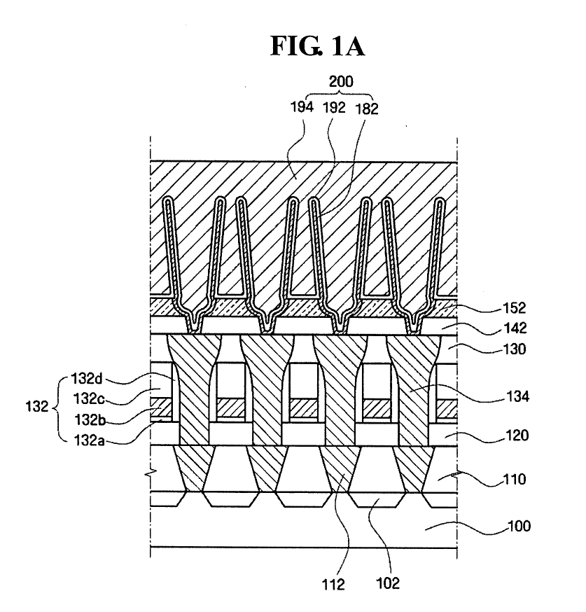

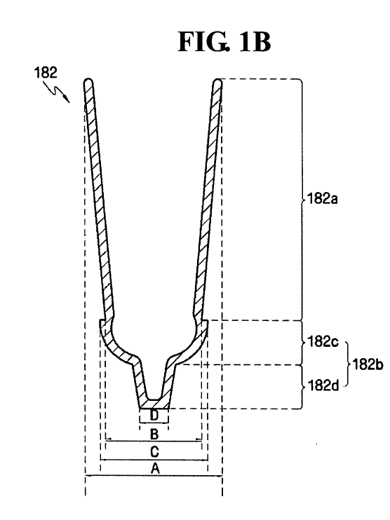

With reference to FIGS. 1A and 1B, a semiconductor memory device according to exemplary embodiments will be described.

FIG. 1A illustrates a cross-sectional view of a semiconductor memory device according to exemplary embodiments. FIG. 1B illustrates a cross-sectional view of a storage node electrode included in the semiconductor memory device according to exemplary embodiments.

As illustrated in FIGS. 1A and 1B, a semiconductor substrate 100 may be divided into a field region and an active region by an isolation layer 102, for example. A first interlayer insulating layer 110, which may include contact pads 112, may be on the semiconductor substrate 100. The contact pads 112 may be formed of a conductive material, such as, but not limited to, a polysilicon doped with impurities of high concentration, and/or a metal material. The contact pads 112 may be electrically connected to an impurity region (not shown) formed in the semiconductor substrate 100. Further, a gate electrode (not shown) may be formed between the contact pads 112. The contact pads 112 may electrically connect the impurity region. Further, the contact pads 112 may also be electrically connected to a bit line 132 and a storage node electrode 182, which may be located above the contact pads 112.

A second interlayer insulating layer 120 may be formed on the first interlayer insulating layer 110, and the bit lines 132 may be on the second interlayer insulating layer 120. As a result, the lower gate electrode (not shown) may be insulated from the bit line 132. Further, a bit line contact plug (not shown), which may electrically connect the bit line 132 and the impurity region (not shown) in the semiconductor substrate 100, may be formed in the second interlayer insulating layer 120. Moreover, the bit line 132 may be on the bit line contact plug (not shown).

The bit line 132 may include a diffusion preventing layer 132a, a metal layer 132b and an insulating layer 132c. Spacers 132d may be located at side walls of the bit line 132.

A third interlayer insulating layer 130 may be on the second interlayer insulating layer 120, where the bit lines 132 may be formed. Storage node contact plugs 134 may be located between the bit lines 132 and above a region between the second insulating layer 120 and the third interlayer insulating layer 130. The storage node contact plug 134 may be connected to the contact pad 112, located below the storage node contact plug 134. Thus, the storage node contact plug 134 may electrically connect the storage node electrode 182 to the impurity region (not shown).

As illustrated in FIG. 1A, because the storage node contact plug 134 may be between the bit lines 132, a contact area may increase between the storage node contact plug 134 and the storage node electrode 182 due to the storage node contact plug 134 having an expanded upper portion. Further, because the storage node electrode 182 may be diagonally disposed, integration may be increased.

A buffer insulating layer 142 and an etch stopper layer 152 may be on the third interlayer insulating layer 130, which may expose the surface of the storage node contact plugs 134. As an exemplary embodiment, the buffer insulating layer 142 and the etch stopper layer 152 may be laminated on the third interlayer insulating layer 130. A lower portion of each of the storage node electrodes 182 may be located in the buffer insulating layer 142 and the etch stopper layer 152. The storage node electrode 182 may be in contact with the storage node contact plug 134. As an exemplary embodiment, the lower portion of the storage node electrode 182 may be generally Y-shaped, and the generally Y-shaped lower portion may interface, e.g., electrically connect, with the storage node contact plug 134. One skilled in the art should appreciate that the term “interface” may also be described as “touch”, “attach”, “link”, “bond”, “join”, “fix”, “unite”, etc. It should further be appreciated that the element(s) and/or layer(s), e.g., between the generally Y-shaped lower portion and storage node contact plug 134, may interface, directly interface or interface to other element(s) or layer(s) and/or intervening element(s) or layer(s).

Referring to FIG. 1B, the storage node electrode 182 located on the storage node contact plug 134 may include a cylindrical body 182a and a generally Y-shaped connecting portion 182b, which may extend from a lower portion of the body 182a and interface with the storage node contact plug 134.

The cylindrical body 182a may have a generally cylindrical shape, e.g., a width that may decrease and/or reduce toward the lower portion. Further, the generally Y-shaped connecting portion 182b may include an expansion portion 182c, which may be connected to the lower portion of the cylindrical body 182a, and a contact portion 182d, which may be connected to the expansion portion 182c. The contact portion 182d may interface with the storage node contact plug 134 located below. Accordingly, the contact portion 182d of the generally Y-shaped connecting portion 182b may be located in the buffer insulating layer 142 on the third interlayer insulating layer 130, and the expansion portion 182c may be located in the etch stopper layer 152.

The expansion portion 182c located in the etch stopper layer 152 have may rounded (or curved) side walls. It should be appreciated that other shapes may be employed to form the side walls. The storage node electrode 182 may have widths of varying dimensions, e.g., A, B, C and D. In particular, the width C of the expansion portion 182c may be larger than a width B of the lower portion of the body 182a. Further, the width C may be larger than the width A of an upper portion of the body 182a, e.g., within a range where the expansion portion 182c is not in contact with expansion portions 182c of other storage electrodes 182 located at both sides of the storage electrode 182.

The width D of the contact portion 182d, which may be located in the buffer insulating layer 142 and connected to the expansion portion 182c, may be smaller than the width C of the expansion portion 182c. Further, width D may be smaller than the width B of the lower portion of the body 182a.

The generally Y-shaped connecting portion 182b of the storage node electrode 182 may have a side wall profile that may be rounded. One skilled in the art would appreciated that the term “rounded” may also be described as “curved”, “bowed”, “coiled”, “arched”, “warped” and etc.

Because the side walls of the storage node electrode 182 may be rounded in the etch stopper layer 152, the side wall profile of the storage node electrode 182 may not provide a rapid step in the etch stopper layer 152.

Further, by reducing the width D of the contact portion 182d of the generally Y-shaped connection portion 182b, the contact portion 182d that may interface with the storage node contact plug 134 may be prevented and/or reduced from being separated from the storage node contact plug 134.

Moreover, referring again to FIG. 1A, a dielectric layer 192 may be conformally formed on the storage node electrodes 182 along the surface of the storage node electrodes 182 and the etch stopper layer 152. The dielectric layer 192 may also have the generally Y-shaped configuration corresponding to the shape of the generally Y-shaped lower portion. A plate electrode 194 may then completely or substantially cover the cylindrical-type storage node electrodes 182, whereby each storage node electrodes 182 may have the generally Y-shaped lower portion.

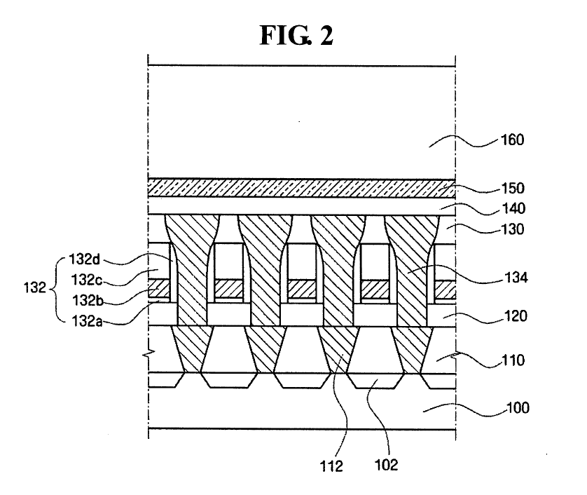

Hereinafter, a method of fabricating a semiconductor memory device according to exemplary embodiments will be described in detail with reference to FIGS. 2 to 8.

FIGS. 2 to 8 illustrate cross-sectional views of stages in processes of fabricating a semiconductor memory device according to exemplary embodiments.

As illustrated in FIG. 2, a gate electrode (not shown) may be formed on the semiconductor substrate 100, which may be divided into a field region and an active region by the isolation layer 102. An ion implantation process may be performed in the semiconductor substrate 100 at both sides of the gate electrode (not shown) so as to form an impurity region (not shown).

An insulating material may then be deposited on an upper portion of the semiconductor substrate 100 in which the gate electrode (not shown) and the impurity region (not shown) may be formed. A chemical mechanical polishing (CMP) process and/or an etch back process, for example, may then be performed so as to planarize the upper portion. It should be appreciated that other processes may be employed to planarize the upper portion of the insulating layer. As a result, the first interlayer insulating layer 110 may be formed.

A general photolithography process, for example, may be performed on the first interlayer insulating layer 110 so as to form contact holes through which the impurity region (not shown) in the semiconductor substrate 100 may be exposed. When the contact holes are formed on the first interlayer insulating layer 110, e.g., formed of silicon oxide by using etching gas that may have a high etching selectivity against the gate electrode (not shown), the contact holes may be self-aligned in respect to the gate electrode (not shown). Through the contact holes, the impurity region (not shown) in the semiconductor substrate 100 may be exposed.

A conductive material, such as, but not limited to, a polysilicon doped with impurities of high concentration and/or a metal material that buries the contract holes, may be deposited over the entire or substantially entire surface of the first interlayer insulating layer 110 where the contact holes are formed. As a result, a conductive layer may be formed. The conductive layer may then be planarized until an the upper portion of the first interlayer insulating layer 110 is exposed so that the self-aligned contact pads 112 may be formed in the first interlayer insulating layer 110.

An insulating material may then be deposited on the upper portion of the first interlayer insulating layer 110, which may include the contact pads 112, and planarized so as to form the second interlayer insulating layer 120. Bit line contact holes may then be formed in the second interlayer insulating layer 120. A conductive material may be deposited and planarized, such that bit line contact plugs (not shown) may be formed in the second interlayer insulating layer 120. In an exemplary embodiment, the bit line contact plug (not shown) may be selectively connected to the contact pad 112 located in the first interlayer insulating layer 110.

Bit lines 132, which may be connected to the bit line contact plugs (not shown), may then be formed on the second interlayer insulating layer 120. The bit lines 132 may include the diffusion preventing layer 132a, the metal layer 132b, and the insulating layer 132c, which may be laminated. Spacers 132d may be formed at side walls of the bit line 132. The diffusion preventing layer 132a may be formed of a titanium/titanium nitride (Ti/TiN) layer, for example, and the metal layer 132b may be formed of a tungsten (W) layer, for example. The insulating layer 132c and the spacer 132d may be formed of a nitride layer, for example. It should be appreciated that the diffusion preventing layer 132a, the metal layer 132b, the insulating layer 132c and the spacer 132d may be composed of other materials beside the ones mentioned above, and may be formed by processes other than lamination. In another exemplary embodiment, the bit line 132 may be formed of, for example, a polysilicon doped with impurities of high concentration instead of the diffusion preventing layer 132a and the metal layer 132b.

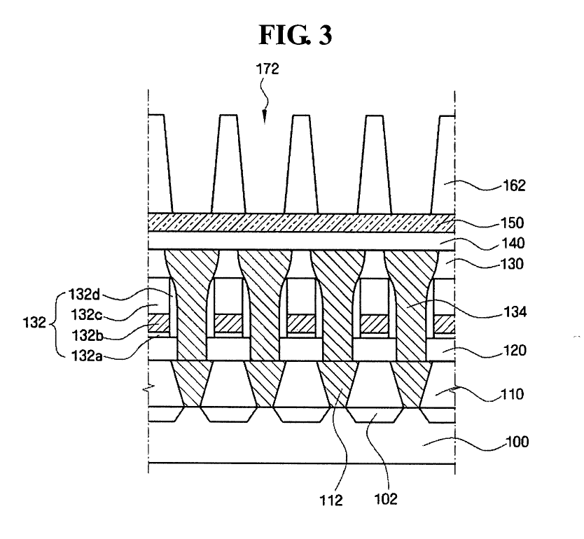

After the bit lines 132 are formed on the second interlayer insulating layer 120, as illustrated in FIG. 3, an insulating material that buries the bit lines 132 may be deposited over the entire or substantially entire surface thereof, and planarized so as to form the third interlayer insulating layer 130.

A general photolithography process, for example, may then be performed on the second and third interlayer insulating layers 120 and 130, respectively, so as to form contact holes. The contact holes may expose the contact pads 112, which may be located below the interlayer insulating layers 120 and 130. Moreover, an upper portion of the contact hole may be expanded so as to increase the contact area between the storage node contact plug 134 and a storage node electrode 182 (shown in FIG. 1A). The contact hole may then be filled with a conductive material and/or a metal material, for example, and planarized so that a complete structure of the storage node contact plug 134 may be formed.

A buffer insulating layer 140, an etch stopper layer 150, and a sacrificial insulating layer 160 may then be laminated on the third interlayer insulating layer 130, which may expose the surface of the storage node contact plugs 134. As an exemplary embodiment, the buffer insulating layer 140 may be formed of silicon oxide, such as, but not limited to, BSG (BoroSilicate Glass), PSG (PhosphoSilicate Glass), BPSG (BoroPhosphoSilicate Glass), TEOS (Tetra ethyl ortho silicate), and/or USG (Undoped silicate Glass). The etch stopper layer 150 may be used as an etch endpoint layer when the sacrificial insulating layer 160 formed on the etch stopper layer 150 is etched. Further, the etch stopper layer 150 may be formed of a material that may have a wet etching ratio higher than the buffer insulating layer 140 and the sacrificial insulating layer 160. For example, the etch stopper layer 150 may be formed of a silicon nitride layer. It should be appreciated that other materials may be used to form the etch stopper layer 150. The buffer insulating layer 140 and the etch stopper layer 150 may be formed with a thickness in the range of about 400 Å to about 600 Å.

The sacrificial insulating layer 160 may be formed by depositing at least one of a PE-TEOS (Plasma Enhanced Tetra Ethyl Ortho Silicate) oxide layer, a HDP (High Density Plasma) layer, and/or a P—SiH₄ oxide layer. The sacrificial insulating layer 160 may be formed with a thickness of about 3,000 Å to about 6,000 Å.

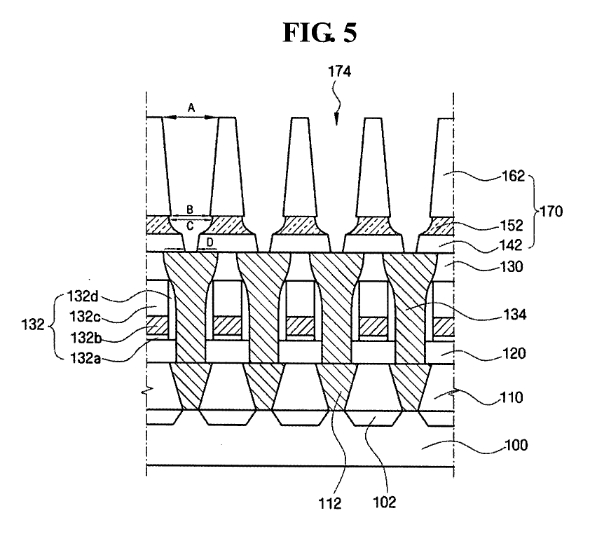

Further, as illustrated in FIG. 3, a selective dry etching process, for example, on the sacrificial insulating layer 160 may be performed using a mask for forming storage node forming holes (refer to reference numeral 174 of FIG. 5), so as to form cylindrical body-forming holes 172. The dry etching process may be performed using, for example, but not limited to, a CFx-based etch gas (e.g., C₄F₆ or C₃F₈). The cylindrical body-forming hole 172 that may be formed on the sacrificial insulating layer 160 may have an inclination from the upper portion toward the lower portion (e.g., the cylindrical body-forming hole 172 may have a smaller diameter at the lower portion than at the upper portion) due to constraints of the dry etching process.

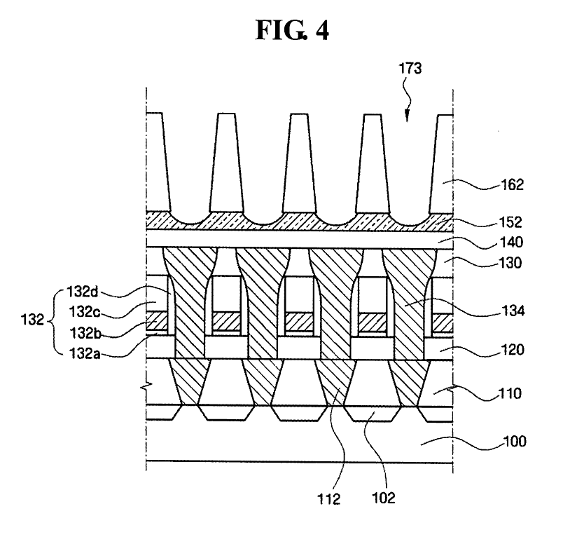

Referring to FIG. 4, a wet etching process, for example, may be performed on a portion of the etch stopper layer 150 that may be exposed by the cylindrical body-forming holes 172. The wet etching process may be performed within a range where the etch stopper layer 152 may not be connected to lower portions of holes 173 located at both sides. Therefore, the lower portion of the cylindrical body forming hole 172 formed in the sacrificial insulating layer 162 may be a recess (e.g., depression, indentation, dent, dimple, dip, niche, nook, etc), such that the hole 173 having a rounded lower portion may be formed due to an anisotropic etching, for example. Therefore, the width of the holes 173 in the etch stopper layer 152 may increase, and thus, the surface area may also increase. During the etching process, an etchant that contains, for example, but not limit to, a phosphoric acid (H₃PO₄) solution, may be used as a wet etching solution.

The cylindrical body-forming holes 172 may be formed in the sacrificial insulating layer 162, and a wet etching process may be performed on the portion of the etch stopper layer 150 located below the sacrificial insulating layer 162. As a result, generation of a rapid step due to difference of etching selectivity between the sacrificial insulating layer 162 and the etch stopper layer 152 may be prevented and/or reduced.

Referring to FIG. 5, a dry etching process, for example, may be performed on the remaining portion of the etch stopper layer 152 and the buffer insulating layer 140 so as to expose the storage node contact plugs 134. Accordingly, a mold 170 having storage node electrode forming holes 174 may be completed, e.g., the mold 170 may be formed over the buffer insulating layer 142, the etch stopper layer 152, and the sacrificial insulating layer 162. The storage node electrode forming holes 174 formed in the mold 170 may have a generally Y-shaped lower portion. The generally Y-shaped lower portion may be formed in the buffer insulating layer 142 and the etch stopper layer 152.

When the dry etching process on the etch stopper layer 152 and the buffer insulating layer 142 is performed, the rounded side wall profile (formed when the wet etching process on the etch stopper layer 152 is performed) may be maintained. Further, when the buffer insulating layer 142 is etched, the etch stopper layer 152, which may have the rounded (or curved) side walls and located above the buffer insulating layer 142, may serve as a mask. This may connect the buffer insulating layer 142 to the side walls in the etch stopper layer 152. Further, the width D of the hole in the buffer insulating layer 142 may be smaller (or reduced) than the width C of the hole in the etch stopper layer 152.

As a result, the diameter of the storage node electrode forming hole 174 formed in the mold 170 may have various widths in accordance to the sacrificial insulating layer 162, the etch stopper layer 152, and the buffer insulating layer 142. That is, the width B of the hole at the interface between the sacrificial insulating layer 162 and the etch stopper layer 152 may be equal to or smaller than the diameter A at the surface of the sacrificial insulating layer 162, e.g., at an opening of the storage node electrode forming hole 174. Further, the width C of the hole in the etch stopper layer 152 having the rounded side walls may be greater than the width B of the hole at the interface between the sacrificial insulating layer 162 and the etch stopper layer 152. Moreover, the width D at the bottom of the storage node electrode forming hole, which the storage node contact plug 134 may be exposed, may be smaller than the width C in the etch stopper layer 152 and/or the width B at the interface between the sacrificial insulating layer 162 and the etch stopper layer 152.

Accordingly, as illustrated in FIG. 5, when forming the storage node forming hole 174, the lower surface area may increase, and the area exposing the storage node contact plug 134 may decrease (or be reduced). Moreover, when the storage node forming holes 174 are formed, the result of separation from the storage node contact plugs 134 may be minimized even if the storage node forming holes 174 is misaligned to the storage node contact plugs 134.

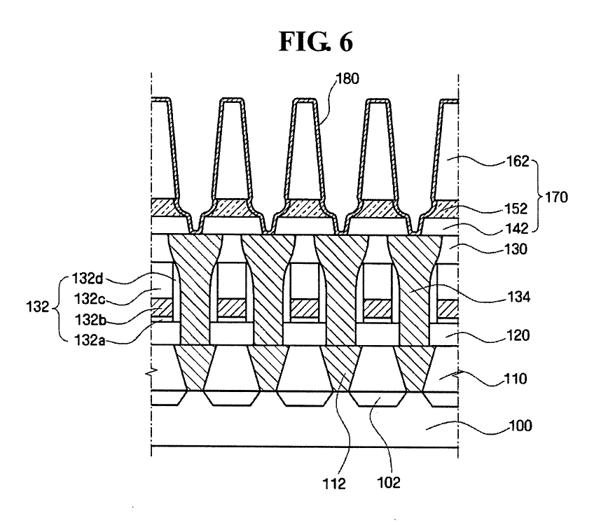

Referring to FIG. 6, a storage node electrode forming conductive layer 180 may be conformally deposited along the surface of the mold 170 where the storage node electrode forming holes 174 may be formed. The storage node electrode forming conductive layer 180 may be formed by depositing, for example, but not limited to, a polysilicon doped with impurities and/or a metal material. It should be appreciated that other materials may be deposited to form the storage node electrode forming conductive layer 180.

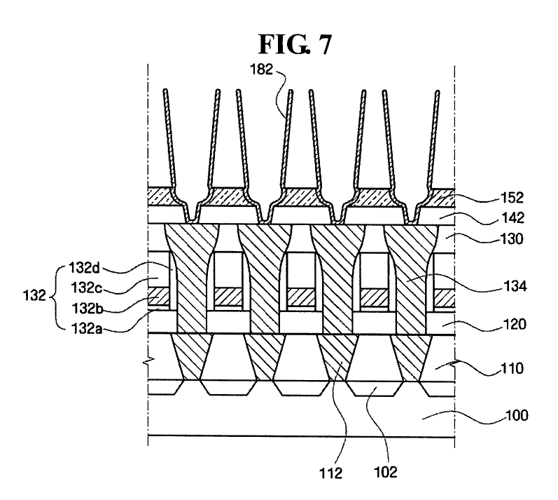

An insulating material having a good gap-filling characteristic, for example, may then be deposited over the storage node electrode forming conductive layer 180. A chemical mechanical polishing (CMP) process and/or a dry etch back process, for example, on the insulating material may be performed until the mold 170 is exposed. The insulating material remaining in the sacrificial insulating layer 162 and the storage node electrodes 182 may then be removed by the wet etching process, for example. As a result, as illustrated in FIG. 7, a complete structure of the storage node electrodes 182 may be formed. Moreover, the remaining buffer insulating layer 142 and the etch stopper layer 152 may support the generally Y-shaped lower portions of the storage node electrodes 182 so that the storage node electrodes 182 may be prevented and/or reduced from falling, e.g., breaking, collapsing, fracturing, rupturing, etc.

Referring back to FIG. 1B, a complete structure of the storage node electrodes 182 having the cylindrical body 182a and the generally Y-shaped connecting portion 182b, which may extend from the lower portion of the body 182a and may contact the storage node contact plug 134, may be illustrated. Further, the generally Y-shaped connecting portion 182b may include the expansion portion 182c, which may be located in the etch stopper layer 152 and may have the rounded (or curved) side walls, and the contact portion 182d, which may be located in the buffer insulating layer 142 and may contact the storage node contact plug 134. Accordingly, because the lower portion of the storage node electrode 182 may have the generally Y-shaped lower portion, the surface area of the storage node electrode 182 may increase. As a result, when the dielectric layer 192 is formed on the lower portions of the storage node electrodes 182 along the surface thereof, the dielectric layer 192 may be easily deposited.

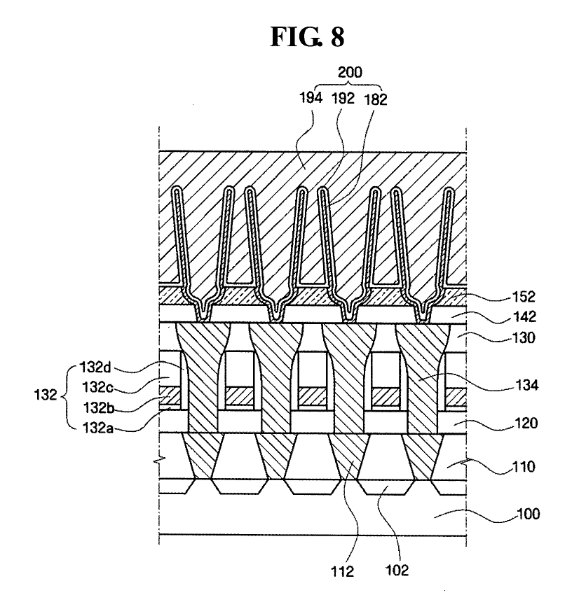

Referring to FIG. 8, the dielectric layer 192 may be conformally deposited along the surface of the storage node electrode 182 and the etch stopper layer 152. A high dielectric material, such as, but not limited to, a tantalum oxide layer Ta₂O₅, an aluminum oxide layer Al₂O₃, and/or a hafnium oxide layer HfO₂, may be deposited so as to form the dielectric layer 192.

Further, the dielectric layer 192 formed along the surface of the storage node electrodes 182 may be uniformly formed. The dielectric layer 192 may also be formed on the lower surface of the storage node electrodes 182 due to the side wall profile of the storage node electrodes 182 not having a rapid step. Therefore, defects of the semiconductor memory device, which may be caused by deposition defects of the dielectric layer 192, may be prevented and/or reduced.

The polysilicon doped with impurities and/or a metal material, for example, may then be deposited on the dielectric layer 192 so as to form the plate electrode 194. This results in a complete structure of the capacitor 200.

Exemplary embodiments relate to a semiconductor memory device and a method of fabricating the same by forming storage node electrodes having lower portions that may have rounded (or curved) side walls and being generally Y-shaped, and may be located in the etch stopper layer and the buffer insulating layer.

Exemplary embodiments may also prevent and/or reduce a dielectric layer from being non-uniformly deposited, even on the lower portion of the storage node electrode.

Exemplary embodiments may provide a portion having a reduced width coming in contact with a storage node contact plug while preventing and/or reducing separation of the storage node electrode from the storage node contact plug.

Exemplary embodiments may provide side walls of a storage node electrode that may be located in an etch stopper layer as being rounded (or curved), so as to increase a surface area of the storage node electrode. The increase surface area may result in an increase in capacitance.

In the figures, the dimensions of layers and regions may be exaggerated for clarity of illustration. It will also be understood that when an element or layer is referred to as being “on”, “disposed on” or “connected to” another element or layer, it can be directly on, directly disposed on or connected to the other element or layer or intervening elements or layers may be present. In contrast, when an element is referred to as being “directly on,” “directly disposed on” or “directly connected to” another element or layer, there are no intervening elements or layers present. Further, it will be understood that when a layer is referred to as being “under” or “above” another layer, it can be directly under or directly above, and one or more intervening layers may also be present. In addition, it will also be understood that when a layer is referred to as being “between” two layers, it can be the only layer between the two layers, or one or more intervening layers may also be present. Like numbers refer to like elements throughout. As used herein, the term “and/or” includes any and all combinations of one or more of the associated listed items.

Spatially relative terms, such as “beneath,” “below,” “lower,” “above,” “upper” and the like, may be used herein for ease of description to describe one element or feature relationship to another element(s) or feature(s) as illustrated in the figures. It will be understood that the spatially relative terms are intended to encompass different orientations of the device in use or operation in addition to the orientation depicted in the figures. For example, if the device in the figures is turned over (or upside down), elements or layers described as “below” or “beneath” other elements or layers would then be oriented “above” the other elements or layers. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized embodiments (and intermediate structures) of exemplary embodiments. As such, variations from the shapes of the illustrations as a result, for exemplary, of manufacturing techniques and/or tolerances, are to be expected. Thus, exemplary embodiments should not be construed as limited to the particular shapes of regions illustrated herein but are to include deviations in shapes that result, for exemplary, from manufacturing. For example, elements and/or layers illustrated as a rectangular or flat, may typically, have rounded or curved features at its edges. Thus, the regions illustrated in the figures are schematic in nature and their shapes are not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A semiconductor memory device, comprising:
a semiconductor substrate;
a plurality of storage node contact plugs above the semiconductor substrate; and
a plurality of storage node electrodes, each of the plurality of storage node electrodes being located respectively above each of the plurality of storage node contact plugs,
wherein each of the storage node electrodes includes a cylindrical body and a generally Y-shaped connection portion extending from the cylindrical body and interfacing with the storage node contact plugs.

2. The semiconductor memory device as claimed in claim 1, wherein the generally Y-shaped connection portion comprises an expansion portion connected to a lower portion of the cylindrical body and a contact portion which is in contact with the storage node contact plug.

3. The semiconductor memory device as claimed in claim 2, wherein a width of the expansion portion is larger than a width of the lower portion of the cylindrical body and the contact portion.

4. The semiconductor memory device as claimed in claim 3, wherein a width of the contact portion is smaller than a width of the lower portion of the body.

5. The semiconductor memory device as claimed in claim 1, further comprising:
a buffer insulating layer; and
an etch stopper layer,
wherein the generally Y-shaped connection portion is in the buffer insulating layer and the etch stopper layer.

6. The semiconductor memory device as claimed in claim 5, wherein:
the expansion portion of the generally Y-shaped connection portion is in the etch stopper layer; and
the contact portion is in the buffer insulating layer.

7. The semiconductor memory device as claimed in claim 6, wherein the expansion portion has rounded side walls in the etch stopper layer.

8. The semiconductor memory device as claimed in claim 6, wherein the etch stopper layer is formed of a material having a wet etching rate higher than the buffer insulating layer.

9. The semiconductor memory device as claimed in claim 6, wherein the buffer insulating layer and the etch stopper layer have a thickness in a range of about 400 Å to about 600 Å.

10. A method of fabricating a semiconductor memory device, the method comprising:
forming a plurality of storage node contact plugs above a semiconductor substrate; and
forming a plurality of storage node electrodes, each of the plurality of storage node electrodes being located respectively above each of the plurality of storage node contact plugs,
wherein each of the storage node electrodes includes a cylindrical body and a generally Y-shaped connection portion extending from the cylindrical body and interfacing with the storage node contact plugs.

11. The method as claimed in claim 10, wherein the generally Y-shaped connection portion comprises an expansion portion connected to a lower portion of the cylindrical body and a contact portion which is in contact with the storage node contact plug.

12. The method as claimed in claim 11, wherein a width of the expansion portion is larger than a width of the lower portion of the cylindrical body and the contact portion.

13. The method as claimed in claim 12, wherein a width of the contact portion is smaller than a width of the lower portion of the body.

14. The method as claimed in claim 10, further comprising:
a buffer insulating layer; and
an etch stopper layer,
wherein the generally Y-shaped connection portion is in the buffer insulating layer and the etch stopper layer.

15. The method as claimed in claim 14, further comprising:
forming the buffer insulating layer, the etch stopper layer, and a sacrificial insulating layer on the storage node contact plugs;
selectively etching the sacrificial insulating layer until the etch stopper layer is exposed so as to form cylindrical body forming holes;
performing an isotropic etching process on a portion of the etch stopper layer that is exposed through the cylindrical body forming holes;
performing an anisotropic etching process on the remaining portion of the etch stopper layer and the buffer insulating layer until the storage node contact plugs are exposed so as to form storage node electrode forming holes, each of which has a generally Y-shaped lower portion; and
conformally forming the storage node electrodes along the storage node electrode forming holes.

16. The method as claimed in claim 15, wherein the buffer insulating layer and the etch stopper layer are formed with a thickness in a range of about 400 Å to about 600 Å.

17. The method as claimed in claim 15, wherein the etch stopper layer is formed of a material having a wet etching rate higher than the buffer insulating layer.

18. A method of fabricating a semiconductor memory device, the method comprising:
laminating a buffer insulating layer, an etch stopper layer, and a sacrificial insulating layer on storage node contact plugs above a semiconductor substrate;
selectively performing an anisotropic etching process on the sacrificial insulating layer until the etch stopper layer is exposed so as to form cylindrical body forming holes;
performing an isotropic etching process on a portion of the stop etch layer that is exposed through the cylindrical body forming holes, such that a lower portion of each of the cylindrical body forming holes is rounded;
performing an anisotropic etching process on the remaining portion of the etch stopper layer and the buffer insulating layer so as to form storage node forming holes that are connected to the cylindrical body forming holes and have generally Y-shaped lower portions that expose the surface of the storage node contact plugs; and
conformally forming storage node electrodes along the storage node forming holes.

19. The method as claimed in claim 18, wherein the etch stopper layer is formed of a material that has a wet etching rate higher than the sacrificial insulating layer and the buffer insulating layer.

20. The method as claimed in claim 18, wherein the buffer insulating layer and the etch stopper layer have a thickness in a range of about 400 Å to about 600 Å.
